(19) United States
(12) Patent Application Publication
(10) Pub. No.: US 2025/0351620 A1
(43) Pub. Date: Nov. 13, 2025

(54) LIGHT-EMITTING ELEMENT AND DISPLAY DEVICE

(71) Applicant: Sharp Display Technology Corporation, Kameyama City, Mie (JP)

(72) Inventors: JUN SAKUMA, Sakai City, Osaka (JP); YASUSHI ASAOKA, Sakai City, Osaka (JP); Sentaro KIDA, Sakai City, Osaka (JP); Takahiro ADACHI, Sakai City, Osaka (JP); Kota ADACHI, Sakai City, Osaka (JP)

(21) Appl. No.: 18/864,694

(22) PCT Filed: Jul. 27, 2022
(86) PCT No.: PCT/JP2022/028872

§ 371 Date: Nov. 11, 2024

(51) Int. Cl. H10H 20/815; H10H 20/816; H10H 20/833; H10H 29/14; H10K 50/165; H10K 50/828; H10K 102/10

(52) U.S. Cl. CPC H10H 20/815; H10H 20/816; H10H 20/833; H10H 29/14; H10K 50/165; H10K 50/828; H10K 2102/102; H10K 2102/103

(57) ABSTRACT

A light-emitting element includes an anode and a cathode, a light-emitting layer positioned between the anode and the cathode, a functional layer positioned between the light-emitting layer and the cathode, and containing Zn and O as elements, and an organic layer having insulating properties and being in contact with the functional layer and the cathode. The organic layer contains a polymer having a long alkyl chain.

### TECHNICAL FIELD

An aspect of the disclosure relates to a light-emitting element.

### BACKGROUND ART

PTL 1 below discloses a configuration of an organic electro-luminescence (EL) element including a cathode buffer layer.

### CITATION LIST

### Patent Literature

PTL 1: WO 2009/130858

### SUMMARY

### Technical Problem

It is desired to reduce a risk of deterioration of a light-emitting element.

### Solution to Problem

A light-emitting element according to an aspect of the disclosure includes an anode and a cathode, a light-emitting layer positioned between the anode and the cathode, a functional layer positioned between the light-emitting layer and the cathode and containing Zn and O as elements, and an organic layer having insulating properties and being in contact with the functional layer and the cathode.

A display device according to an aspect of the disclosure includes a first anode, a second anode, and a cathode facing the first anode and the second anode, a first light-emitting layer positioned above the first anode, a second light-emitting layer positioned above the second anode, a first functional layer positioned above the first light-emitting layer and containing Zn and O as elements, a second functional layer positioned above the second light-emitting layer and containing Zn and O as elements, a first organic layer having insulating properties and being in contact with the first functional layer and the cathode, and a second organic layer having insulating properties and being in contact with the second functional layer and the cathode.

### Advantageous Effects of Disclosure

According to an aspect of the disclosure, it is possible to reduce a risk of deterioration of a light-emitting element.

### BRIEF DESCRIPTION OF DRAWINGS

FIG. 1 is a cross-sectional view illustrating a configuration example of a light-emitting element according to a first embodiment.

FIG. 2 is a cross-sectional view illustrating a configuration example of a display device according to a second embodiment.

FIG. 3 is a cross-sectional view illustrating a configuration example of the display device of a modified example.

FIG. 4 is a cross-sectional view illustrating a configuration example of the display device according to a third embodiment.

FIG. 5 is a cross-sectional view illustrating a configuration example of the display device according to a fourth embodiment.

### DESCRIPTION OF EMBODIMENTS

### First Embodiment

A light-emitting element 1 according to a first embodiment will be described below. For convenience of explanation, components (constituent elements) having the same function as the components described in the first embodiment are denoted with the same reference signs in each of the following embodiments, and descriptions are not repeated. For the sake of simplification, descriptions of known technical matters are omitted as appropriate. Each component, each material, and each numerical value described in the present specification are merely examples unless there is a contradiction. Therefore, for example, unless there is a contradiction in particular, a positional relationship between the components is not limited to the examples in each of the figures. Also, each of the figures are not necessarily illustrated to scale.

### Configuration of Light-Emitting Element 1

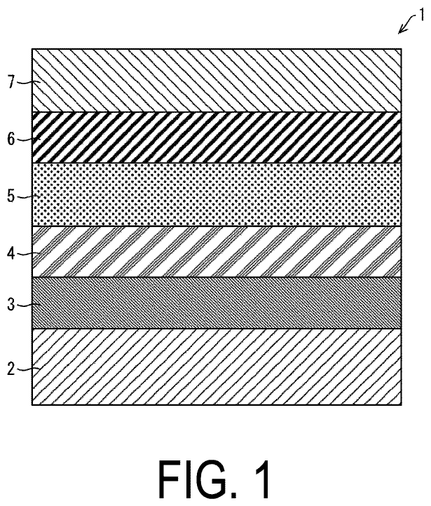

FIG. 1 is a cross-sectional view illustrating a configuration example of the light-emitting element 1. The light-emitting element 1 may include an anode 2, a hole transport layer (HTL) 3, a light-emitting layer 4, a functional layer 5, an organic layer 6, and a cathode 7 in this order from a lower side to an upper side. In this way, the cathode 7 may be positioned above the anode 2. A substrate (not illustrated in FIG. 1) that supports each portion of the light-emitting element 1 may be positioned below the anode 2.

The anode 2 provides holes to the light-emitting layer 4. The cathode 7 provides electrons to the light-emitting layer 4. At least one of the anode 2 and the cathode 7 may be formed of an optical transparent material. A transparent conductive material can be used as the optical transparent material, for example. Examples of the transparent conductive material include indium tin oxide (ITO) and indium zinc oxide (IZO). Since these materials have high transmittance of visible light, luminous efficiency of the light-emitting element 1 can be improved.

At least one of the anode 2 and the cathode 7 may be formed of a light-reflective material. A metal material can be used as the light-reflective material, for example. Examples of the metal material include aluminum (Al) and silver (Ag). Another example of the metal material includes an alloy containing Al or Ag (example: MgAg). Since these materials have high reflectivity of visible light, the luminous efficiency of the light-emitting element 1 can be improved.

Thus, for example, the cathode 7 may include at least one of Al, Ag, ITO, and IZO. The cathode 7 may be positioned to face the anode 2. Therefore, for example, the light-emitting element 1 may be a light-emitting element of a conventional bottom-emitting type or a conventional top-emitting type. Alternatively, the light-emitting element 1 may be a light-emitting element of an inverted bottom-emitting type or an inverted top-emitting type.

The hole transport layer 3 may be positioned between the anode 2 and the light-emitting layer 4. The hole transport layer 3 may include a known hole transport material. According to the hole transport layer 3, the luminous efficiency of the light-emitting element 1 can be improved.

The light-emitting layer 4 may be positioned between the anode 2 and the cathode 7. In the example of FIG. 1, the light-emitting layer 4 is positioned between the hole transport layer 3 and the functional layer 5. The light-emitting layer 4 may include any light-emitting material that emits light by recombination of a hole provided from the anode 2 and an electron transported from the cathode 7. The light-emitting element 1 may be configured to emit light in the light-emitting layer 4 by applying a voltage or a current between the anode 2 and the cathode 7. Therefore, the light-emitting layer 4 may be an inorganic EL light-emitting layer or an organic EL light-emitting layer.

The functional layer 5 may be positioned between the light-emitting layer 4 and the cathode 7. In the example of FIG. 1, the functional layer 5 is positioned between the light-emitting layer 4 and the organic layer 6. The functional layer 5 contains Zn and O as elements. Thus, as an example, the functional layer 5 may contain a zinc oxide-based material (ZnO-based material).

Examples of the zinc oxide-based material include ZnO, MgZnO, AlZnO, and LiZnO. Therefore, the functional layer 5 may contain at least one of ZnO, MgZnO, AlZnO, and LiZnO as the zinc oxide-based material.

The zinc oxide-based material described above is an example of an electron transport material. Therefore, the functional layer 5 can function as an electron transport layer (ETL). When the functional layer 5 as the electron transport layer is included, the luminous efficiency of the light-emitting element 1 can be improved. The functional layer 5 as the electron transport layer may be referred to as a ZnO-based ETL. In particular, when the light-emitting layer 4 is an inorganic EL light-emitting layer, the luminous efficiency of the light-emitting element 1 can be remarkably improved by the ZnO-based ETL.

The organic layer 6 may be positioned to be in contact with the functional layer 5 and the cathode 7. The organic layer 6 may be configured to have insulating properties. Thus, the organic layer 6 may include any insulating material. As will be described below, the organic layer 6 serves as a buffer layer (intermediate layer) for reducing a risk of deterioration of the functional layer 5 and the cathode 7. Therefore, the organic layer 6 may be referred to as, for example, an organic buffer layer.

### Effect of Light-Emitting Element 1

As described above, the functional layer 5 contains Zn as an element. Zn can contribute to improvement in the luminous efficiency of the light-emitting element 1. On the other hand, since Zn is an amphoteric element, Zn can react with many elements. For example, Zn can significantly react with metal elements and oxygen elements.

In addition, when the organic layer 6 is not provided, a metal element may diffuse between the functional layer 5 and the cathode 7. Therefore, in the absence of the organic layer 6, a chemical reaction between the functional layer 5 and the cathode 7 may significantly occur due to the fact that the functional layer 5 contains Zn. As a result, a change in quality (example: corrosion) of the functional layer 5 and the cathode 7 may occur. Thus, the chemical reaction may lead to deterioration of the functional layer 5 and the cathode 7.

On the other hand, when the organic layer 6 is present, the diffusion of the metal element between the functional layer 5 and the cathode 7 can be reduced. Therefore, even when the functional layer 5 containing Zn is used, it is possible to reduce a risk of occurrence of the chemical reaction. As a result, it is possible to reduce the risk that the functional layer 5 and the cathode 7 deteriorate. As described above, according to the organic layer 6, it is possible to reduce a risk of deterioration of the light-emitting element 1.

As an example, the organic layer 6 may include a polymer having a long alkyl chain. Examples of the polymer having a long alkyl chain include polyvinylpyrrolidone (PVP) and polyvinyl alcohol (PVA).

Polymers having a long alkyl chain have good packing properties. In addition, the polymers having a long alkyl chain do not have that many reactive groups. Therefore, the polymers having a long alkyl chain contribute to reducing the risk of occurrence of the chemical reaction (in other words, reducing the risk of deterioration of the light-emitting element 1).

As another example, the organic layer 6 may include a fluorine-based polymer. Many fluorine-based polymers have water repellency. Therefore, the fluorine-based polymer in the organic layer 6 can be a water repellent polymer. Examples of the water repellent polymer include a fluoroalkyl phosphonic acid and a fluoroalkane.

According to the fluorine-based polymer (example: water repellent polymer), it is possible to reduce the risk that moisture, which promotes the occurrence of the chemical reaction, enters a layer below the organic layer 6. Therefore, the fluorine-based polymer also contributes to reducing the risk of deterioration of the light-emitting element 1.

From the viewpoint of reducing the risk of deterioration of the light-emitting element 1, it is preferable that the organic layer 6 be positioned at an upper side as much as possible in the light-emitting element 1. In other words, it is preferable to position the cathode 7 at an upper side as possible in the light-emitting element 1. For this reason, FIG. 1 illustrates a configuration in which the cathode 7 is positioned above the anode 2.

Incidentally, as a thickness of the organic layer 6 increases, a current flowing through the light-emitting layer 4 may decrease. In other words, as the thickness of the organic layer 6 increases, the luminous efficiency of the light-emitting layer 4 may decrease. Therefore, from the viewpoint of avoiding a decrease in efficiency of the light-emitting element 1, it is preferable that the thickness of the organic layer 6 be not so large. Thus, for example, the thickness of the organic layer 6 may be set to be smaller than a thickness of the functional layer 5.

However, when the thickness of the organic layer 6 is too small, an effect of reducing the diffusion of the metal element between the functional layer 5 and the cathode 7 (in other words, the effect of reducing the risk of occurrence of the chemical reaction) may be reduced. Therefore, it is preferable that the thickness of the organic layer 6 be not too small. Thus, as an example, the thickness of the organic layer 6 may be from 1 to 20 nm.

By setting the thickness of the organic layer 6 as described above, it is possible to reduce a risk that the efficiency of the light-emitting element 1 is reduced while reducing the risk that the light-emitting element 1 is deteriorated by the organic layer 6. As a result, the light-emitting element 1 having a long lifetime and high efficiency can be achieved.

### Second Embodiment

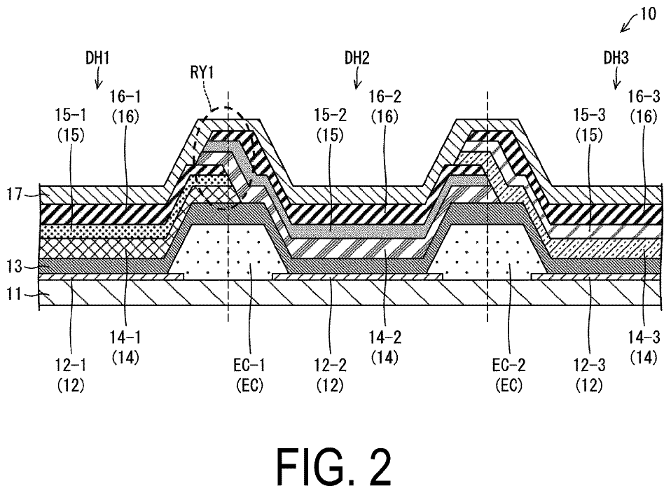

FIG. 2 is a cross-sectional view illustrating a configuration example of a display device 10 according to a second embodiment. The display device 10 may include a first light-emitting element DH1 and a second light-emitting element DH2. The display device 10 may further include a third light-emitting element DH3. Each of the first light-emitting element DH1 to the third light-emitting element DH3 corresponds to the above-described light-emitting element 1. Therefore, effects similar to those of the first embodiment can also be exhibited in the display device 10.

A relationship between each part of the first light-emitting element DH1 and each part of the second light-emitting element DH2 also applies to each part of the second light-emitting element DH2 and each part of the third light-emitting element DH3 as long as there is no contradiction in content. Therefore, in the following, each part of the first light-emitting element DH1 and each part of the second light-emitting element DH2 will be mainly described.

As an example, the display device 10 may include a substrate 11, an anode 12, a hole transport layer 13, a light-emitting layer 14, a functional layer 15, an organic layer 16, and a cathode 17 in this order from the lower side to the upper side.

As illustrated in FIG. 2, the display device 10 may include a first anode 12-1, a second anode 12-2, and a third anode 12-3 as the anode 12. The first anode 12-1 to the third anode 12-3 are anodes of the first light-emitting element DH1 to the third light-emitting element DH3, respectively. The anode 12 may be positioned to face the cathode 17.

The display device 10 may include a first light-emitting layer 14-1, a second light-emitting layer 14-2, and a third light-emitting layer 14-3 as the light-emitting layer 14. The first light-emitting layer 14-1 to the third light-emitting layer 14-3 are light-emitting layers of the first light-emitting element DH1 to the third light-emitting element DH3, respectively. The first light-emitting layer 14-1 to the third light-emitting layer 14-3 may be positioned above the first anode 12-1 to the third anode 12-3, respectively. The first light-emitting layer 14-1 to the third light-emitting layer 14-3 may be configured to emit light in different wavelength bands (example: light of different colors), respectively. As an example, the first light-emitting layer 14-1 may be a red light-emitting layer, the second light-emitting layer 14-2 may be a green light-emitting layer, and the third light-emitting layer 14-3 may be a blue light-emitting layer. In this case, the first light-emitting element DH1 is a red light-emitting element, the second light-emitting element DH2 is a green light-emitting element, and the third light-emitting element DH3 is a blue light-emitting element.

As described in the first embodiment, the functional layer 15 may contain Zn and O as elements. The display device 10 may include a first functional layer 15-1, a second functional layer 15-2, and a third functional layer 15-3 as the functional layer 15. The first functional layer 15-1 to the third functional layer 15-3 may be positioned above the first light-emitting layer 14-1 to the third light-emitting layer 14-3, respectively.

As described in the first embodiment, the organic layer 16 may have insulating properties. The display device 10 may include a first organic layer 16-1, a second organic layer 16-2, and a third organic layer 16-3 as the organic layer 16.

The first organic layer 16-1 may be in contact with the first functional layer 15-1 and the cathode 17. Similarly, the second organic layer 16-2 may be in contact with the second functional layer 15-2 and the cathode 17. Further, the third organic layer 16-3 may be in contact with the third functional layer and the cathode 17.

The display device 10 may include an edge cover film EC that covers an edge of the anode 12. In FIG. 2, two edge cover films EC are illustrated. As an example, the edge cover film EC may be a bank that partitions each light-emitting element in the display device 10. When the two edge cover films EC are distinguished from each other, one of the edge cover films EC is represented by a reference sign EC-1 and the other edge cover film EC is represented by a reference sign EC-2.

In the example of FIG. 2, the edge cover film EC-1 is positioned at a boundary portion between the first light-emitting element DH1 and the second light-emitting element DH2 so as to partition the first light-emitting element DH1 and the second light-emitting element DH2. The edge cover film EC-2 is positioned at a boundary portion between the second light-emitting element DH2 and the third light-emitting element DH3 so as to partition the second light-emitting element DH2 and the third light-emitting element DH3.

Therefore, as illustrated in FIG. 2, the edge cover film EC-1 may cover an edge of the first anode 12-1. In the display device 10, as illustrated in a region RY1 of FIG. 2, above the edge cover film EC-1, the first functional layer 15-1 and the first organic layer 16-1 may overlap with each other. Therefore, in the display device 10, above the edge cover film EC-1, the first light-emitting layer 14-1, the first functional layer 15-1, and the first organic layer 16-1 may overlap with each other.

In addition, the edge cover film EC-1 may cover an edge of the second anode 12-2. In the display device 10, above the edge cover film EC-1, the second organic layer 16-2 may be positioned above the first organic layer 16-1. Therefore, above the edge cover film EC-1, the second functional layer 15-2, the second organic layer 16-2, and the cathode 17 may overlap with each other.

In addition, in the display device 10, above the edge cover film EC-1, the first functional layer 15-1, the first organic layer 16-1, the second functional layer 15-2, and the second organic layer 16-2 may be positioned in this order. Therefore, for example, above the edge cover film EC-1, an end face of the first light-emitting layer 14-1 may be in contact with the second light-emitting layer 14-2. Above the edge cover film EC-1, an end face of the first functional layer 15-1 and an end face of the first organic layer 16-1 may be in contact with the second light-emitting layer 14-2.

As an example, the light-emitting layer 14, the functional layer 15, and the organic layer 16 in the display device 10 may be formed by multilayer photolithography. According to the multilayer photolithography, as illustrated in FIG. 2, above the edge cover film EC-1, the first light-emitting layer 14-1 and the second light-emitting layer 14-2 can be overlapped with each other. Therefore, for example, since the second light-emitting layer 14-2 can be positioned above the first light-emitting layer 14-1, it is possible to achieve each configuration (each positional relationship) described above in FIG. 2.

As a result, for example, the organic layer 16 can be positioned so that the first functional layer 15-1 and the cathode 17 do not come into contact with each other. For example, as illustrated in FIG. 2, above the edge cover film EC-1, a pair of the first functional layer 15-1 and the first organic layer 16-1 (referred to as a first pair for convenience), the second light-emitting layer 14-2, and a pair of the second functional layer 15-2 and the second organic layer 16-2 (referred to as a second pair for convenience) can be arranged in this order. According to this positional relationship, the contact described above does not occur. As described above, according to the display device 10, it is possible to more reliably reduce a risk of occurrence of the contact. Therefore, according to the display device 10, it is possible to more effectively reduce the risk of occurrence of deterioration of the display device.

In addition, according to the display device 10, it is also possible to reduce contact between the light-emitting layer 14 and the functional layer 15 and the cathode 17 by the organic layer 16. Therefore, according to the display device 10, a leakage current can be reduced so that the efficiency of the display device can also be improved. As described above, according to the display device 10, for example, a display device having a long lifetime and high efficiency can be achieved.

Further, in the display device 10, the thicknesses of the first functional layer 15-1 and the second functional layer 15-2 may be different from each other. The constituent materials of the first functional layer 15-1 and the second functional layer 15-2 may be different from each other. As described above, the first functional layer 15-1 and the second functional layer 15-2 having different design specifications may be used for the first light-emitting layer 14-1 and the second light-emitting layer 14-2, respectively.

By individually designing the first functional layer 15-1 and the second functional layer 15-2, light emission characteristics of the first light-emitting element DH1 and the second light-emitting element DH2 can be individually optimized. As a result, the efficiency of the display device 10 can be further improved.

### Modified Example

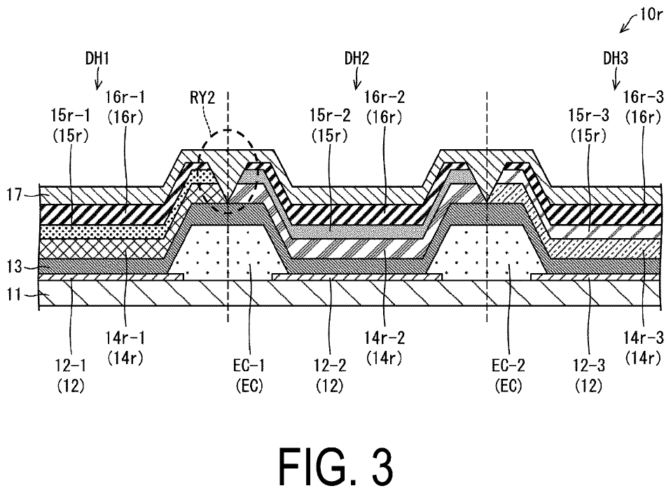

FIG. 3 is a cross-sectional view illustrating a configuration example of a display device 10r according to a modified example. A light-emitting layer 14r, a functional layer 15r, and an organic layer 16r in the example of FIG. 3 are the light-emitting layer, the functional layer, and the organic layer in the modified example, respectively. A first light-emitting layer 14r-1 to a third light-emitting layer 14r-3 are the first light-emitting layer to the third light-emitting layer in the modified example, respectively. A first functional layer 15r-1 to a third functional layer 15r-3 are the first functional layer to the third functional layer in the modified example, respectively. A first organic layer 16r-1 to a third organic layer 16r-3 are the first organic layer to the third organic layer in the modified example, respectively.

As illustrated in a region RY2 of FIG. 3, in the display device 10r, above the edge cover film EC-1, the first light-emitting layer 14r-1 and the first functional layer 15r-1 are in contact with the cathode 17. Similarly, above the edge cover film EC-1, the second light-emitting layer 14r-2 and the second functional layer 15r-2 are in contact with the cathode 17.

However, a contact area in the display device 10r is smaller than that of a display device not having the organic layer 16. Thus, a lifetime and efficiency of the display device 10r is better than that of a display device not including the organic layer 16. Therefore, the configuration of the modified example is also included in one aspect of the disclosure. By adopting the configuration of the second embodiment described above (or a configuration of a third embodiment or a fourth embodiment described later) instead of the configuration of the modified example, it is possible to achieve a display device having a longer lifetime and higher efficiency.

### Third Embodiment

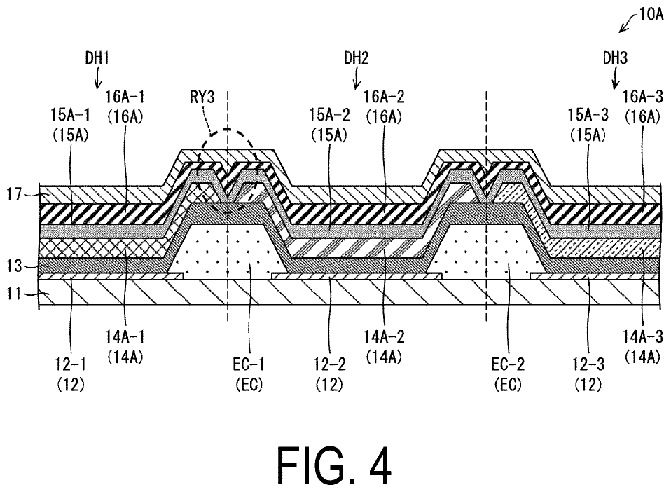

FIG. 4 is a cross-sectional view illustrating a configuration example of a display device 10A according to a third embodiment. The display device 10A is a modified example of the display device 10r. A light-emitting layer 14A, a functional layer 15A, and an organic layer 16A in the example of FIG. 4 are the light-emitting layer, the functional layer, and the organic layer in the display device 10A, respectively. A first light-emitting layer 14A-1 to a third light-emitting layer 14A-3 are the first light-emitting layer to the third light-emitting layer in the third embodiment, respectively. A first functional layer 15A-1 to a third functional layer 15A-3 are the first functional layer to the third functional layer in the third embodiment, respectively. A first organic layer 16A-1 to a third organic layer 16A-3 are the first organic layer to the third organic layer in the third embodiment, respectively.

As illustrated in a region RY3 of FIG. 4, in the display device 10A, above the edge cover film EC-1, the first organic layer 16A-1 and the second organic layer 16A-2 may be coupled to each other in the same layer. Further, above the edge cover film EC-1, an end portion of the first functional layer 15A-1 may be in contact with an end face of the first light-emitting layer 14A-1. Similarly, above the edge cover film EC-1, an end portion of the second functional layer 15A-2 may be in contact with an end face of the second light-emitting layer 14A-2.

As illustrated in FIG. 4, the organic layer 16A can be positioned so that the first functional layer 15A-1 and the cathode 17 do not come into contact with each other even by the configuration of the display device 10A. Thus, similar effects as those of the second embodiment can be exhibited by the third embodiment. In addition, according to the configuration of the display device 10A, it is also possible to position the organic layer 16A such that there is no contact between the functional layer 15A and the cathode 17. Therefore, according to the third embodiment, a remarkable effect can be exhibited as compared with the second embodiment.

### Fourth Embodiment

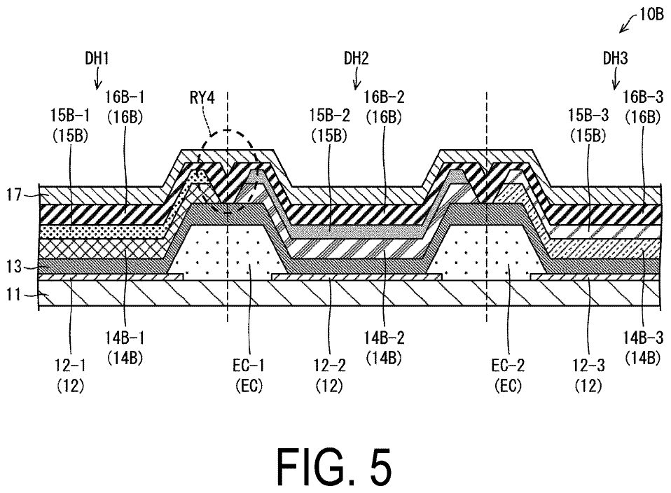

FIG. 5 is a cross-sectional view illustrating a configuration example of a display device 10B according to a fourth embodiment. The display device 10B is a modified example of the display device 10A. A light-emitting layer 14B, a functional layer 15B, and an organic layer 16B in the example of FIG. 5 are the light-emitting layer, the functional layer, and the organic layer in the display device 10B, respectively. A first light-emitting layer 14B-1 to a third light-emitting layer 14B-3 are the first light-emitting layer to the third light-emitting layer in the fourth embodiment, respectively. A first functional layer 15B-1 to a third functional layer 15B-3 are the first functional layer to the third functional layer in the fourth embodiment, respectively. A first organic layer 16B-1 to a third organic layer 16B-3 are the first organic layer to the third organic layer in the fourth embodiment, respectively.

As illustrated in a region RY4 of FIG. 5, in the display device 10B, above the edge cover film EC-1, the first organic layer 16B-1 and the second organic layer 16B-2 may be coupled to each other in the same layer. Above the edge cover film EC-1, an end portion of the first organic layer 16B-1 may be in contact with an end face of the first light-emitting layer 14B-1 and an end face of the first functional layer 15B-1. Similarly, above the edge cover film EC-1, an end portion of the second organic layer 16B-2 may be in contact with an end face of the second light-emitting layer 14B-2 and an end face of the second functional layer 15B-2.

As illustrated in FIG. 5, the organic layer 16B can be positioned so that the first functional layer 15B-1 and the cathode 17 do not come into contact with each other even by the configuration of the display device 10B. Thus, similar effects as those of the second embodiment can be exhibited by the fourth embodiment. In addition, depending on the configuration of the display device 10B, the organic layer 16B can be positioned so that the functional layer 15B and the cathode 17 do not come into contact with each other. Therefore, remarkable effects as those of the third embodiment can be exhibited by the fourth embodiment.

### Appendix

An aspect of the disclosure is not limited to each of the embodiments described above, and various modifications may be made within the scope of the claims. Embodiments obtained by appropriately combining technical approaches disclosed in the different embodiments also fall within the technical scope of the aspect of the disclosure. Furthermore, novel technical features can be formed by combining the technical approaches disclosed in each of the embodiments.

### REFERENCE SIGNS LIST

1 Light-emitting element
2, 12 Anode
4, 14, 14r, 14A, 14B Light-emitting layer
5, 15, 15r, 15A, 15B Functional layer
6, 16, 16r, 16A, 16B Organic layer
7, 17 Cathode
10, 10r, 10A, 10B Display device
12-1, 12r-1, 12A-1, 12B-1 First anode
12-2, 12r-2, 12A-2, 12B-2 Second anode
14-1, 14r-1, 14A-1, 14B-1 First light-emitting layer
14-2, 14r-2, 14A-2, 14B-2 Second light-emitting layer
15-1, 15r-1, 15A-1, 15B-1 First functional layer
15-2, 15r-2, 15A-2, 15B-2 Second functional layer
16-1, 16r-1, 16A-1, 16B-1 First organic layer
16-2, 16r-2, 16A-2, 16B-2 Second organic layer
EC-1 Edge cover film

1. A light-emitting element, comprising:
an anode and a cathode;
a light-emitting layer positioned between the anode and the cathode;
a functional layer positioned between the light-emitting layer and the cathode and containing Zn and O as elements; and
an organic layer having insulating properties and being in contact with the functional layer and the cathode,
wherein the organic layer contains a polymer having a long alkyl chain.

2-6. (canceled)

7. The light-emitting element according to claim 1,
wherein the polymer is polyvinylpyrrolidone (PVP) or polyvinyl alcohol (PVA).

8. A light-emitting element, comprising:
an anode and a cathode;
a light-emitting layer positioned between the anode and the cathode;
a functional layer positioned between the light-emitting layer and the cathode and containing Zn and O as elements; and
an organic layer having insulating properties and being in contact with the functional layer and the cathode,
wherein the organic layer contains a fluorine-based polymer.

9. The light-emitting element according to claim 8,
wherein the fluorine-based polymer is a water repellent polymer.

10. The light-emitting element according to claim 9,
wherein the water repellent polymer is a fluoroalkyl phosphonic acid or a fluoroalkane.

11. The light-emitting element according to claim 1,
wherein the cathode contains at least one of Al, Ag, ITO, and IZO.

12. The light-emitting element according to claim 1,
wherein the cathode is positioned above the anode.

13. A display device, comprising:
a first anode, a second anode, and a cathode facing the first anode and the second anode;
a first light-emitting layer positioned above the first anode;
a second light-emitting layer positioned above the second anode;
a first functional layer positioned above the first light-emitting layer and containing Zn and O as elements;
a second functional layer positioned above the second light-emitting layer and containing Zn and O as elements;
a first organic layer having insulating properties and being in contact with the first functional layer and the cathode; and
a second organic layer having insulating properties and being in contact with the second functional layer and the cathode.

14. The display device according to claim 13, further comprising:
an edge cover film covering an edge of the first anode,
wherein the edge cover film, the first functional layer and the first organic layer overlap with each other.

15. The display device according to claim 14,
wherein above the edge cover film, the first light-emitting layer, the first functional layer, and the first organic layer overlap with each other.

16. The display device according to claim 13,
wherein a thickness of the first functional layer and a thickness of the second functional layer are different from each other.

17. The display device according to claim 13,
wherein a constituent material of the first functional layer and a constituent material of the second functional layer are different from each other.

18. The display device according to claim 13,
wherein the first organic layer and the second organic layer are coupled to each other in the same layer.

19. The display device according to claim 13,
wherein the second organic layer is positioned above the first organic layer.

20. The display device according to claim 14,
wherein the edge cover film covers an edge of the second anode, and
above the edge cover film, the second functional layer, the second organic layer, and the cathode overlap with each other.

21. The display device according to claim 14,
wherein above the edge cover film, the first functional layer, the first organic layer, the second functional layer, and the second organic layer are positioned in this order.

22. The display device according to claim 14,
wherein above the edge cover film, an end face of the first light-emitting layer is in contact with the second light-emitting layer.

23. The display device according to claim 14,
wherein above the edge cover film, an end face of the first functional layer and an end face of the first organic layer are in contact with the second light-emitting layer.

24. The display device according to claim 18,
wherein an end portion of the first functional layer is in contact with an end face of the first light-emitting layer.

25. The display device according to claim 18,
wherein an end portion of the first organic layer is in contact with an end face of the first light-emitting layer and an end face of the first functional layer.
